(19) United States
(12) Patent Application Publication
(10) Pub. No.: US 2024/0324312 A1
(43) Pub. Date: Sep. 26, 2024

(54) DISPLAY APPARATUS

(71) Applicant: Samsung Display Co., Ltd., Yongin-si (KR)

(72) Inventors: Guanghai Jin, Yongin-si (KR); Yongseog Kim, Yongin-si (KR)

(21) Appl. No.: 18/604,382

(22) Filed: Mar. 13, 2024

(30) Foreign Application Priority Data
Mar. 24, 2023 (KR) 10-2023-0039055
Apr. 12, 2023 (KR) 10-2023-0048360

(51) Int. Cl. H10K 59/122; H10K 59/35

(52) U.S. Cl. CPC H10K 59/122; H10K 59/351; H10K 59/352; H10K 59/353

(57) ABSTRACT

A display apparatus includes a substrate, first, second, and third organic light-emitting diodes configured to respectively emit light of first, second, and third colors above the substrate, and a bank layer defining a first opening, second openings, and a third opening, the first opening overlapping the first organic light-emitting diode, at least one of the second openings overlapping the second organic light-emitting diode, and the third opening overlapping the third organic light-emitting diode, wherein the bank layer further defines a fourth opening arranged between the first opening and the third opening in plan view, wherein the first opening, the second openings, and the third opening include respective edges substantially parallel to, or substantially complimentary to, respective boundary lines of the fourth opening, and wherein the first opening, the second openings, and the third opening include five or more interior angles.

### CROSS-REFERENCE TO RELATED APPLICATIONS

This application claims priority to, and benefit of, Korean Patent Application No. 10-2023-0039055, filed on Mar. 24, 2023, and Korean Patent Application No. 10-2023-0048360, filed on Apr. 12, 2023, in the Korean Intellectual Property Office, the entire contents of which are incorporated herein by reference.

### BACKGROUND

### 1. Field

One or more embodiments relate to a structure of a display apparatus.

### 2. Description of Related Art

A display apparatus visually displays data. Recently, the usage of display apparatuses has diversified. In addition, as display apparatuses have become thinner and more lightweight, their range of use has gradually been extended.

As a display apparatus is variously utilized, there may be various methods of designing the shape of a display apparatus, and also, functions that may be combined or associated with a display apparatus have increased.

### SUMMARY

One or more embodiments include a display apparatus with a reduced loss of an aperture ratio and with improved display quality. However, the present disclosure is not limited to the above aspect.

Additional aspects will be set forth in part in the description which follows and, in part, will be apparent from the description, or may be learned by practice of the presented embodiments of the disclosure.

According to one or more embodiments, a display apparatus includes a substrate, a first organic light-emitting diode configured to emit light of a first color, a second organic light-emitting diode configured to emit light of a second color, and a third organic light-emitting diode configured to emit light of a third color above the substrate, and a bank layer defining a first opening, second openings, and a third opening, the first opening overlapping the first organic light-emitting diode, at least one of the second openings overlapping the second organic light-emitting diode, and the third opening overlapping the third organic light-emitting diode, wherein the bank layer further defines a fourth opening arranged between the first opening and the third opening in plan view, wherein the first opening, the second openings, and the third opening include respective edges substantially parallel to, or substantially complimentary to, respective boundary lines of the fourth opening, and wherein the first opening, the second openings, and the third opening include five or more interior angles.

The second openings may be arranged along a first column in a first direction, wherein the first opening and the third opening are alternately arranged along a second column parallel to the first column, wherein the second openings are staggered from the first opening and the third opening in the first direction, wherein the first column and the second column are alternately arranged in a second direction crossing the first direction, and wherein the fourth opening is arranged between the first opening and the third opening along the second column.

The second openings may be arranged along a first row in the second direction, wherein the first opening and the third opening are alternately arranged along a second row parallel to the first row, wherein the second openings are arranged in a staggered manner relative to the first opening and the third opening in the second direction, wherein the first row and the second row are alternately arranged in the first direction, and wherein the fourth opening is arranged between respective adjacent ones of the second openings along the first row.

A unit pixel may be repeatedly arranged in the first direction and the second direction on the substrate, the unit pixel including the fourth opening at a center of the unit pixel, the first opening and the third opening adjacent to the fourth opening in the first direction, and the second openings adjacent to two sides of the fourth opening in the second direction.

A number of fourth openings above the substrate may be equal to a number of first openings above the substrate.

In a plan view, a virtual quadrangle may have one of the second openings as a center, wherein first openings are respectively arranged on a first vertex and a third vertex of the virtual quadrangle opposite each other, and third openings are respectively arranged on a second vertex and a fourth vertex of the virtual quadrangle.

The vertices of the virtual quadrangle may be respectively at centroids of the first openings and the third openings in plan view.

The second openings arranged adjacent to each other in the second direction with the fourth opening therebetween may have symmetrical shapes with each other with respect to a virtual straight line passing through a center of the fourth opening in the first direction.

A shape of the fourth opening may be a quadrangle in plan view, and respective edges of the first opening, the second openings, and the third opening that face the fourth opening are straight.

The first opening, the second openings, and the third opening may respectively have a pentagonal shape in plan view.

The fourth opening may include a first edge extending in the second direction, and a second edge extending in the first direction, wherein the first opening includes a first edge facing the fourth opening, the second openings include first edges facing the fourth opening, and the third opening includes a first edge facing the fourth opening.

A length of the first edge of the fourth opening may be greater than a length of the second edge of the fourth opening, wherein the shape of the fourth opening is rectangular.

The first edge of the first opening and the first edge of the third opening may be equal to or greater than the first edges of the second openings in length.

The first edge of the third opening may be equal to or greater than the first edge of the first opening in length.

The first opening may further include a second edge adjacent to the first edge of the first opening, wherein the third opening further includes a second edge adjacent to the first edge of the third opening, and wherein a length of the second edge of the third opening is greater than a length of the second edge of the first opening.

Respective corner portions of the first opening, the second openings, and the third opening may have a round shape in plan view.

The first opening, the second openings, and the third opening may respectively have an octagonal shape in plan view.

A shape of the fourth opening may be a circular shape or an elliptical shape in plan view, wherein respective edges of the first opening, the second openings, and the third opening that face the fourth opening are curved.

The first color may be red, the second color green, and the third color blue.

The display apparatus may further include a fourth organic light-emitting diode overlapping the fourth opening, and configured to emit light of at least one of red, green, blue, or white.

The display apparatus may further include a light-receiving element overlapping the fourth opening.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic plan view of a display apparatus according to one or more embodiments;

FIG. 2 is an equivalent circuit diagram of a circuit connected to an organic light-emitting diode of a display apparatus according to one or more embodiments;

FIG. 3 is a plan view of a configuration of pixels of a portion of a display apparatus according to one or more embodiments;

FIG. 4A is a schematic cross-sectional view of a portion of a display apparatus according to one or more embodiments, and FIG. 4B is a schematic cross-sectional view of a portion of a display apparatus according to one or more other embodiments;

FIG. 5 is a plan view of some of pixels of FIG. 3; and

FIGS. 6 and 7 are plan views of some of pixels of a display apparatus according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

A display apparatus may be used as a display screen of various products including televisions, notebook computers, monitors, advertisement boards, Internet of things (IoT) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the display apparatus according to one or more embodiments may be used in wearable devices including smartwatches, watchphones, glasses-type displays, and head-mounted displays (HMDs). In addition, in one or more embodiments, the display apparatus is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

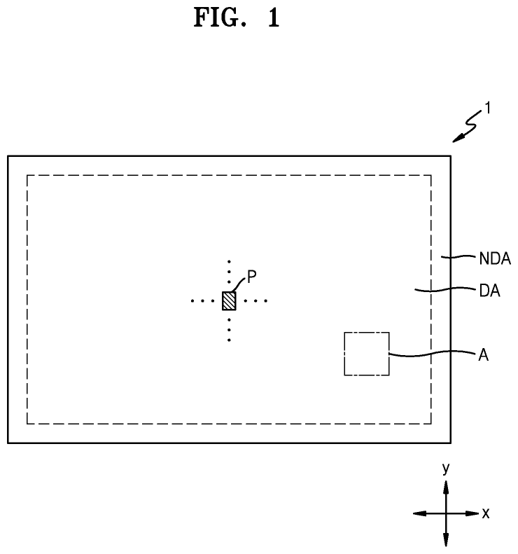

FIG. 1 is a schematic plan view of a display apparatus 1 according to one or more embodiments.

Referring to FIG. 1, the display apparatus 1 may include a display area DA, and a non-display area NDA outside the display area DA. The display apparatus 1 may be configured to display images through an array of a plurality of pixels arranged two-dimensionally in the display area DA.

Each pixel of the display apparatus 1 is a region that may be configured to emit light of a corresponding color. The display apparatus 1 may be configured to display images by using light from the pixels. As an example, the pixel may be configured to emit red, green, blue, or white light.

Each of the pixels may be configured to emit light of a corresponding color using a light-emitting element, for example, an organic light-emitting diode. Each organic light-emitting diode may be configured to emit, for example, red, green, blue, or white light. Each organic light-emitting diode may be connected to a pixel circuit including a thin-film transistor and a capacitor.

The non-display area NDA is a region that is configured not to display images, and may surround the display area DA entirely. A driver or a main power line configured to provide electrical signals or power to pixel circuits may be arranged in the non-display area NDA. A pad may be arranged in the non-display area NDA, wherein the pad is a region to which electronic elements or a printed circuit board may be electrically connected.

As shown in FIG. 1, the display area DA may have a polygonal shape including a quadrangular shape. As an example, the display area DA may have a rectangular shape in which a horizontal length thereof is greater than a vertical length, a rectangular shape in which a horizontal length thereof is less than a vertical length, or a square shape. Alternatively, the display area DA may have various shapes, such as an elliptical shape or a circular shape.

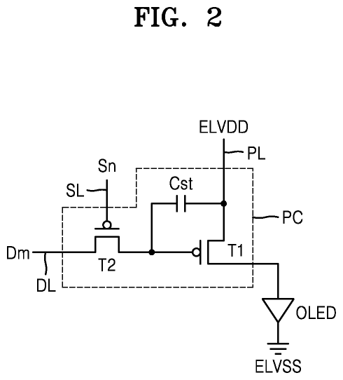

FIG. 2 is an equivalent circuit diagram of a circuit connected to an organic light-emitting diode OLED of the display apparatus 1 according to one or more embodiments.

Referring to FIG. 2, the organic light-emitting diode OLED is electrically connected to a pixel circuit PC. The pixel circuit PC may include a first thin-film transistor T1, a second thin-film transistor T2, and a storage capacitor Cst.

The second thin-film transistor T2 is a switching thin-film transistor, and may be connected to a scan line SL and a data line DL to transfer a data voltage (or a data signal Dm) to the first thin-film transistor T1 based on a switching voltage (or a switching signal Sn), the data voltage being input from the data line DL, and the switching voltage being input from the scan line SL.

The storage capacitor Cst may be connected to the second thin-film transistor T2 and a driving voltage line PL to store a voltage corresponding to a difference between a voltage transferred from the second thin-film transistor T2 and a first power voltage ELVDD supplied to the driving voltage line PL.

The first thin-film transistor T1 is a driving thin-film transistor, and may be connected to the driving voltage line PL and the storage capacitor Cst to control a driving current according to the voltage stored in the storage capacitor Cst, the driving current flowing from the driving voltage line PL to the organic light-emitting diode OLED.

The organic light-emitting diode OLED may be configured to emit light having a corresponding brightness corresponding to the driving current. An opposite electrode (e.g., a cathode) of the organic light-emitting diode OLED may receive a second power voltage ELVSS.

Although it is described with reference to FIG. 2 that the pixel circuit PC includes two thin-film transistors and one storage capacitor, the present disclosure is not limited thereto. The number of thin-film transistors and the number of storage capacitors may be variously changed according to the design of the pixel circuit PC. As an example, the pixel circuit PC may include three or more thin-film transistors. In one or more embodiments, at least one thin-film transistor may be further provided between the first thin-film transistor T1 and the organic light-emitting diode OLED, and the first thin-film transistor T1 may be electrically connected to the organic light-emitting diode OLED through the at least one thin-film transistor.

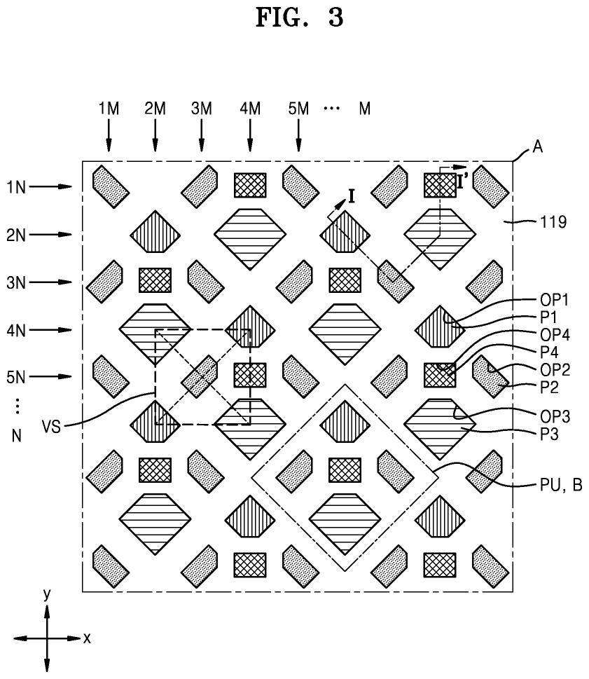

FIG. 3 is a plan view of a configuration of pixels of a portion of the display apparatus according to one or more embodiments.

Referring to FIG. 3, a plurality of pixels may be arranged in the display area DA of the display apparatus. In the present specification, a pixel is a minimum unit configured to implement an image, and denotes an emission area. In the case where an organic light-emitting diode is employed as a display element, the emission area may be defined by the opening of a bank layer 119. As an example, an emission area of a first pixel P1 may be defined by a first opening OP1 of the bank layer 119, an emission area of a second pixel P2 may be defined by a second opening OP2 of the bank layer 119, and an emission area of a third pixel P3 may be defined by a third opening OP3 of the bank layer 119, as described further below.

As shown in FIG. 3, first pixels P1, second pixels P2, and third pixels P3 in the display area DA may be arranged in a PENTILE™ structure (e.g., a RGBG matrix structure, a PENTILE™ matrix structure, or an RGBG structure, PENTILE™ being a registered trademark of Samsung Display Co., Ltd., Republic of Korea). In one or more embodiments, the first pixel P1 may be a red pixel configured to emit red light, the second pixel P2 may be a green pixel configured to emit green light, and the third pixel P3 may be a blue pixel configured to emit blue light.

The shape of each of the first opening OP1, the second opening OP2, and the third opening OP3 may have five or more interior angles. In one or more embodiments, as shown in FIG. 3, the first opening OP1, the second opening OP2, and the third opening OP3 may have a pentagonal shape. For example, the first opening OP1 and the third opening OP3 may have a pentagonal shape in which a corner portion is truncated from a square shape. In addition, the second opening OP2 may have a pentagonal shape in which a corner portion is truncated from a rectangular shape. In this case, a truncated corner of the corner portions of each of the first opening OP1, the second opening OP2, and the third opening OP3 may be a corner portion facing the fourth opening OP4. Accordingly, the first opening OP1, the second opening OP2, and the third opening OP3 may include an edge that is parallel to a boundary line of the fourth opening OP4.

Because the first opening OP1 and the third opening OP3 have a pentagonal shape in which a corner portion is truncated from a square shape, they may be horizontally symmetrical to each other. As an example, each of the first opening OP1 and the third opening OP3 may be horizontally symmetrical with respect to a virtual straight line in a first direction (e.g., a y direction) passing through the central point of the opening. Because the second opening OP2 has a pentagonal shape in which a corner is truncated from a rectangle, the second opening OP2 may not be horizontally symmetrical. However, the second openings OP2 arranged adjacent to each other with the fourth opening OP4 therebetween may be symmetrical to each other with respect to a virtual straight line in the first direction (e.g., the y direction) passing through the central point of the fourth opening OP4.

The first opening OP1 of the first pixel P1, the second opening OP2 of the second pixel P2, and the third opening OP3 of the third pixel P3 may have different areas. In one or more embodiments, the area of the third opening OP3 of the third pixel P3 may be greater than the area of the first opening OP1 of the first pixel P1. In addition, the area of the third opening OP3 of the third pixel P3 may be greater than the area of the second opening OP2 of the second pixel P2. The area of the first opening OP1 of the first pixel P1 may be greater than the area of the second opening OP2 of the second pixel P2. However, the present disclosure is not limited thereto, and the areas of the first to third openings OP1, OP2, and OP3 may be variously modified.

A plurality of second pixels P2 may be arranged apart from each other at a corresponding interval in a first column 1M, a plurality of first pixels P1 and a plurality of third pixels P3 may be alternately arranged in a second column 2M adjacent thereto, a plurality of second pixels P2 may be arranged apart from each other at a corresponding interval in a third column 3M adjacent thereto, and a plurality of first pixels P1 and a plurality of third pixels P3 may be alternately arranged in a fourth column 4M adjacent thereto. Such configurations of the pixels may be repeated up to an M-th column. That is, the second opening OP2 defining the second pixel P2 may be arranged along the first column 1M in the first direction (e.g., the y direction), and the first opening OP1 defining the first pixel P1 and the third opening OP3 defining the third pixel P3 may be alternately arranged along the second column 2M that is parallel to the first column 1M. In this case, the plurality of second pixels P2 arranged in the first column 1M and the plurality of first pixels P1 and the plurality of third pixels P3 arranged in the second column 2M may be alternately arranged with each other. That is, the second opening OP2 may be alternately arranged with the first opening OP1 and the third opening OP3, and the first column 1M and the second column 2M may be alternately arranged in the second direction (e.g., an x direction) and repeated up to the M-th column, noting that every other one of the even columns may have the order of the first and third openings OP1 and OP3 reversed.

The plurality of second pixels P2 arranged in the first column 1M and the plurality of first pixels P1 and the plurality of third pixels P3 arranged in the second column 2M may be alternately arranged with each other. A plurality of second pixels P2 may be arranged apart from each other at a corresponding interval in a first row 1N. A plurality of first pixels P1 and a plurality of third pixels P3 may be alternately arranged in a second row 2N adjacent to the first row 1N. A plurality of second pixels P2 may be arranged apart from each other at a corresponding interval in a third row 3N adjacent to the second row 2N. A plurality of first pixels P1 and a plurality of third pixels P3 may be alternately arranged in a fourth row 4N adjacent to the third row 3N, noting that the order of the first pixels P1 and the third pixels P3 in the fourth row 4N may be opposite to the order in the second row 2N.

Such configurations of the pixels may be repeated up to an N-th row. That is, the second opening OP2 defining the second pixel P2 may be arranged along the first row 1N in the second direction (e.g., the x direction), and the first opening OP1 defining the first pixel P1 and the third opening OP3 defining the third pixel P3 may be alternately arranged along the second row 2N parallel to the first row 1N. In this case, the plurality of second pixels P2 arranged in the first row 1N and the plurality of first pixels P1 and the plurality of third pixels P3 arranged in the second row 2N may be alternately arranged with each other. That is, the second opening OP2 may be alternately arranged with the first opening OP1 and the third opening OP3, and the first row 1N and the second row 2N may be alternately arranged in the first direction (e.g., the y direction) and repeated up to the N-th row.

Such pixel configuration structure may be expressed differently, in which the first pixel P1 and the third pixel P3 may be arranged on vertices of a virtual quadrangle VS with the second pixel P2 approximately centered therein. For example, the first openings OP1 may be arranged on first and third vertices facing each other among the vertices of the virtual quadrangle VS with the center of second opening OP2 positioned approximately at the central point of the quadrangle, and the third openings OP3 may be arranged on second and fourth vertices, which are the remainder of the vertices of the virtual quadrangle VS. The virtual quadrangle VS may be variously changed to a rectangle, a rhombus, a square, and the like.

In this case, the vertices of the virtual quadrangle VS may be positioned at the centroids of the first opening OP1 and the third opening OP3, and the central point of the virtual quadrangle VS may be positioned at the centroid of the second opening OP2. In the present specification, the center of the pixel may denote a geometrical centroid of the shape of the pixel. However, as in FIG. 3, in the case where the first opening OP1 has a pentagonal shape in which a corner portion facing the fourth opening OP4 is truncated, the center of the first opening OP1 may be the same as the center of a square in which a corner portion is not truncated. Likewise, because the second opening OP2 and the third opening OP3 have a pentagonal shape in which a corner portion facing the fourth opening OP4 is truncated from a quadrangle, the center of the second opening OP2 and the third opening OP3 may be the same as the center of the quadrangle in which a corner portion is not truncated.

This configuration structure of the first to third pixels P1, P2, and P3 may be referred to as a pentile matrix structure or a pentile structure. By applying rendering, in which a color of a pixel is represented by sharing the colors of its adjacent pixels, a high resolution may be obtained via a small number of pixels.

Referring to FIG. 3 again, the fourth pixel P4 may be arranged in the display area DA together with the first to third pixels P1, P2, and P3. In one or more embodiments, the fourth pixel P4 may be a white pixel configured to emit white light. Alternatively, in one or more other embodiments, the fourth pixel P4 may be configured to emit at least one of red, green, and/or blue light like one or more of the first, second, and/or third pixels P1, P2, and/or P3. In one or more other embodiments, the fourth pixel P4 may include a light-receiving element configured to detect light. In this case, the emission area or light-receiving area of the fourth pixel P4 may be defined by the fourth opening OP4 of the bank layer 119.

The fourth opening OP4 may have a quadrangular shape. In one or more embodiments, the fourth opening OP4 may have a rectangular shape as in FIG. 3. In one or more other embodiments, the fourth opening OP4 may have a square shape or a rhombus shape. The fourth opening OP4 may be vertically symmetrical or horizontally symmetrical with respect to the central point of the opening. As an example, the fourth opening OP4 may be horizontally symmetrical with respect to a virtual straight line in the first direction (e.g., the y direction) passing through the central point of the opening, and may be vertically symmetrical with respect to a virtual straight line in the second direction (e.g., the x direction) passing through the central point of the opening.

The fourth opening OP4 may be arranged between the first opening OP1 and the third opening OP3 in the first direction (e.g., the y direction), and may be arranged between the second openings OP2 adjacent to each other in the second direction (e.g., the x direction). For example, in the case where the plurality of second openings OP2 are arranged along the first column 1M, and the plurality of first openings OP1 and the plurality of third openings OP3 are arranged along the second column 2M, the fourth openings OP4 may be arranged between the first opening OP1 and the third opening OP3 arranged adjacent to each other along the second column 2M. That is, a pattern of the first opening OP1, the fourth opening OP4, and the third opening OP3 may be repeatedly arranged in the first direction. Likewise, in the case where the plurality of second openings OP2 are arranged along the first row 1N, and the plurality of first openings OP1 and the plurality of third openings OP3 are arranged along the second row 2N, the fourth openings OP4 may be arranged between the second openings OP2 arranged adjacent to each other. That is, a pattern of the second opening OP2, the fourth opening OP4, and the second opening OP2 may be repeatedly arranged in the second direction.

In other words, a unit pixel PU including the first to fourth openings OP1, OP2, OP3, and OP4 may be repeatedly arranged in the display area DA. The unit pixel PU may be repeatedly arranged in the first direction (e.g., the y direction) and the second direction (e.g., the x direction). In this case, the unit pixel PU may include one first opening OP1, two second openings OP2, one third opening OP3, and one fourth opening OP4. For example, the unit pixel PU may include the fourth pixel OP4 arranged at the center of the unit pixel PU, the first opening OP1 and the third opening OP3 arranged adjacent to the fourth opening OP4 in the first direction, and the two second openings OP2 arranged adjacent to the fourth opening OP4 in the second direction. As an example, as in FIG. 3, in the case where the unit pixel PU includes the fourth opening OP4 arranged in the N-th row and an M-th column, the unit pixel PU may include the first opening OP1 arranged in an (N−1)th row and an M-th column, the second opening OP2 arranged in the N-th row and an (M−1)th column, the second opening OP2 arranged in the N-th row and an (M+1)-th column, and the third opening OP3 arranged in an (N+1)-th row and the M-th column.

The number of fourth openings OP4 located on the substrate 100 may be substantially the same as the number of first openings OP1 or the number of third openings OP3. That is, the fourth openings OP4 may not be arranged in all areas between the first openings OP1 and the third openings OP3. As in FIG. 3, the fourth opening OP4 may be arranged between the first opening OP1 and the third opening OP3 such that the first opening OP1 is relatively arranged in the upper portion and the third opening OP3 is relatively arranged in the lower portion in the first direction. That is, the fourth opening OP4 may be arranged such that the pattern of the order of the first opening OP1, the fourth opening OP4, and the third opening OP3 is repeated in the first direction (e.g., the y direction).

However, the present disclosure is not limited to the pixel configuration structure shown in FIG. 3. In one or more other embodiments, the fourth opening OP4 may be arranged between the third opening OP3 and the first opening OP1 such that the third opening OP3 is relatively arranged in the upper portion, and the first opening OP1 is relatively arranged in the lower portion in the first direction. That is, the fourth opening OP4 may be arranged such that the pattern of the order of the third opening OP3, the fourth opening OP4, and the first opening OP1 is repeated in the first direction (e.g., the y direction).

Through this pixel configuration structure, the display apparatus according to one or more embodiments may be configured to implement images of suitable quality while additional openings are suitably arranged. That is, because the first to third openings OP1, OP2, and OP3 have a pentagonal shape in which a corner portion is partially truncated and the fourth opening OP4 is arranged in a resulting surplus area, a loss in an aperture ratio may be reduced, and suitable visibility may be concurrently or substantially simultaneously implemented. In addition, because the fourth opening OP4 may be arranged, the display apparatus according to one or more embodiments may additionally include a light-receiving element, a biosensor, an IR sensor, and the like in addition to a light-emitting element. Accordingly, the use of the display apparatus may be further diversified.

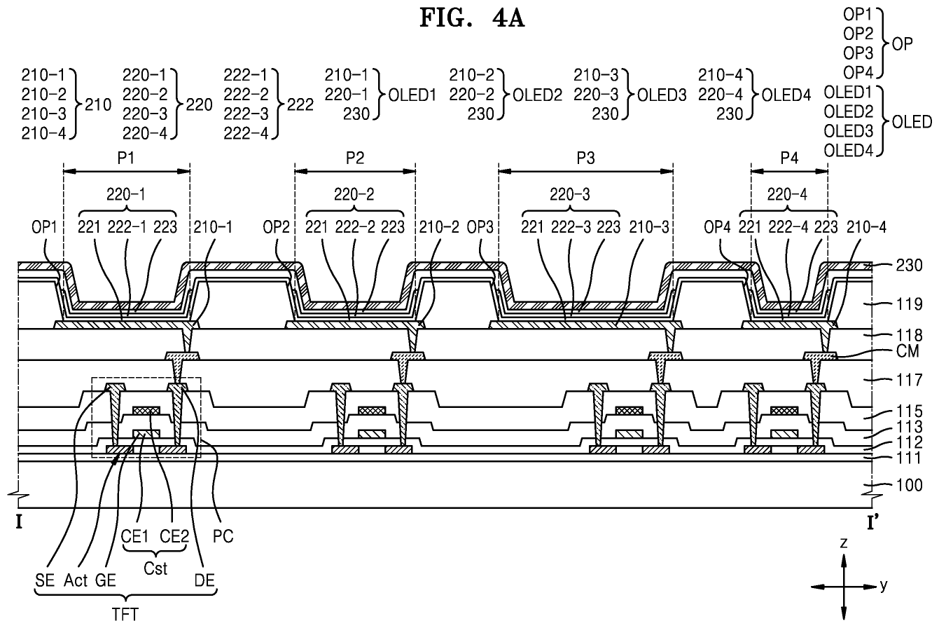

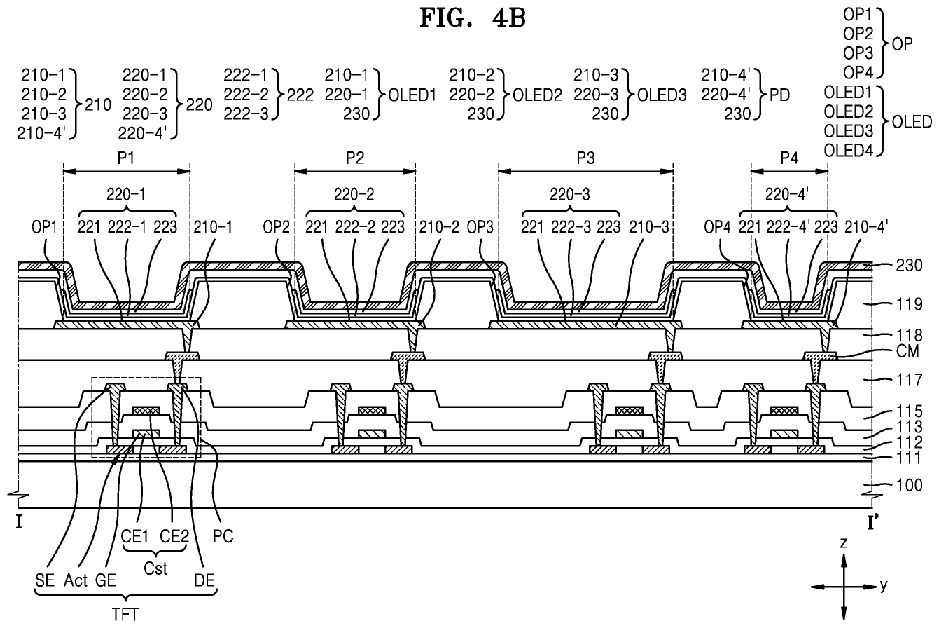

FIG. 4A is a schematic cross-sectional view of a portion of the display apparatus according to one or more embodiments, and FIG. 4B is a schematic cross-sectional view of a portion of the display apparatus according to one or more other embodiments. For example, FIGS. 4A and 4B are cross-sectional views of the display apparatus, taken along the line I-I′ of FIG. 3.

Referring to FIG. 4A, the display apparatus 1 may include the substrate 100, the pixel circuit PC located on the substrate 100, and the organic light-emitting diode OLED located over the pixel circuit PC, and electrically connected to the pixel circuit PC. The organic light-emitting diode OLED may include a first organic light-emitting diode OLED1, a second organic light-emitting diode OLED2, a third organic light-emitting diode OLED3, and a fourth organic light-emitting diode OLED4. Each of the first organic light-emitting diode OLED1, the second organic light-emitting diode OLED2, the third organic light-emitting diode OLED3, and the fourth organic light-emitting diode OLED4 may be electrically connected to the pixel circuit PC, and thus, light emission may be controlled.

The substrate 100 may include glass or a polymer resin. The polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including the polymer resin may be flexible, rollable, or bendable. The substrate 100 may have a multi-layered structure including a layer that includes the polymer resin and an inorganic layer.

A buffer layer 111 may be configured to reduce or block foreign materials, moisture, or external air penetrating from below the substrate 100 and may provide a flat surface on the substrate 100. The buffer layer 111 may include an inorganic insulating material, such as silicon nitride, silicon oxynitride, and silicon oxide, and may include a single-layered structure or a multi-layered structure including the above materials.

The pixel circuit PC may be located on the buffer layer 111, and may include a thin-film transistor TFT and a storage capacitor Cst.

The thin-film transistor TFT may include a semiconductor layer Act, a gate electrode GE, a source electrode SE, and a drain electrode DE, wherein the gate electrode GE overlaps a channel region of the semiconductor layer Act, and the source electrode SE and the drain electrode DE are respectively connected to a source region and a drain region of the semiconductor layer Act. A gate-insulating layer 112 may be located between the semiconductor layer Act and the gate electrode GE, and a first interlayer insulating layer 113 and a second interlayer insulating layer 115 may be located between the gate electrode GE and the source electrode SE, and/or between the gate electrode GE and the drain electrode DE.

The storage capacitor Cst may overlap the thin-film transistor TFT. The storage capacitor Cst may include a first electrode CE1 and a second electrode CE2 overlapping each other. In one or more embodiments, the gate electrode GE of the thin-film transistor TFT may include (e.g., may be the same as) the first electrode CE1 of the storage capacitor Cst. The first interlayer insulating layer 113 may be located between the first electrode CE1 and the second electrode CE2.

The semiconductor layer Act may include polycrystalline silicon. In one or more embodiments, the semiconductor layer Act may include amorphous silicon. In one or more embodiments, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). The semiconductor layer Act may include a channel region, a source region, and a drain region, the source region and the drain region being doped with impurities.

The gate-insulating layer 112 may include an inorganic insulating material, such as silicon nitride, silicon oxynitride, and silicon oxide, and may include a single-layered structure or a multi-layered structure including the above materials.

The gate electrode GE or the first electrode CE1 may include a conductive material of a metal material, such as molybdenum (Mo), aluminum (AI), copper (Cu) and/or titanium (Ti), and may have a single-layered structure or a multi-layered structure including the above materials.

The first interlayer insulating layer 113 may include an inorganic insulating material, such as silicon nitride, silicon oxynitride, and silicon oxide, and may include a single-layered structure or a multi-layered structure including the above materials.

The second electrode CE2 may include aluminum (AI), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including the above metals.

The second interlayer insulating layer 115 may include an inorganic insulating material, such as silicon nitride, silicon oxynitride, and silicon oxide, and may include a single-layered structure or a multi-layered structure including the above materials.

The source electrode SE and/or the drain electrode DE may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including the above materials. As an example, the source electrode SE and/or the drain electrode DE may each have a three-layered structure of a titanium layer/aluminum layer/titanium layer.

The pixel circuit PC including the thin-film transistor TFT and the storage capacitor Cst may be electrically connected to a pixel electrode 210. In one or more embodiments, as shown in FIG. 4, the pixel circuit PC and the pixel electrode 210 may be electrically connected to each other through a contact metal CM. In one or more other embodiments, an additional contact metal may be further located between the pixel circuit PC and the pixel electrode 210. In this case, the pixel circuit PC and the pixel electrode 210 may be electrically connected to each other through a contact metal CM, and through an additional contact metal between the contact metal CM and the pixel electrode 210. Alternatively, the pixel circuit PC and the pixel electrode 210 may be electrically and directly connected to each other without the contact metal CM.

The contact metal CM may be located on a first upper insulating layer 117, and may be connected to the pixel circuit PC through a contact hole formed in the first upper insulating layer 117. The contact metal CM may include aluminum (AI), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including the above materials. In one or more embodiments, the contact metal CM may have a three-layered structure of a titanium layer/an aluminum layer/a titanium layer.

The first upper insulating layer 117 may include an inorganic insulating material and/or an organic insulating material. The inorganic insulating material of the first upper insulating layer 117 may include silicon oxide, silicon oxynitride, and silicon nitride. The organic insulating material of the first upper insulating layer 117 may include acryl, benzocyclobutene (BCB), polyimide, or hexamethyldisiloxane (HMDSO).

A second upper insulating layer 118 may be located on the contact metal CM. The second upper insulating layer 118 may include an inorganic insulating material and/or an organic insulating material. The inorganic insulating material of the second upper insulating layer 118 may include silicon oxide, silicon oxynitride, and silicon nitride. In one or more embodiments, the second upper insulating layer 118 may include the organic insulating material, such as acryl, benzocyclobutene (BCB), polyimide, or hexamethyldisiloxane (HMDSO).

The first organic light-emitting diode OLED1, the second organic light-emitting diode OLED2, the third organic light-emitting diode OLED3, and the fourth organic light-emitting diode OLED4 may be located apart from each other on the second upper insulating layer 118. The first organic light-emitting diode OLED1, the second organic light-emitting diode OLED2, and the third organic light-emitting diode OLED3 may be configured to emit light of different or respective colors. As an example, the first organic light-emitting diode OLED1 may be configured to emit red light, the second organic light-emitting diode OLED2 may be configured to emit green light, and the third organic light-emitting diode OLED3 may be configured to emit blue light. In one or more embodiments, the fourth organic light-emitting diode OLED4 may be configured to emit white light. However, the present disclosure is not limited thereto. In one or more other embodiments, the fourth organic light-emitting diode OLED4 may be configured to emit at least one of red, green, and/or blue light.

Each of the first to fourth organic light-emitting diodes OLED1, OLED2, OLED3, and OLED4 may include the pixel electrode 210, an intermediate layer 220, and an opposite electrode 230. As an example, the first organic light-emitting diode OLED1 may include a first pixel electrode 210-1, a first intermediate layer 220-1, and the opposite electrode 230, the second organic light-emitting diode OLED2 may include a second pixel electrode 210-2, a second intermediate layer 220-2, and the opposite electrode 230, the third organic light-emitting diode OLED3 may include a third pixel electrode 210-3, a third intermediate layer 220-3, and the opposite electrode 230, and the fourth organic light-emitting diode OLED4 may include a fourth pixel electrode 210-4, a fourth intermediate layer 220-4, and the opposite electrode 230. The pixel electrode 210 may be patterned and provided for each pixel, and the opposite electrode 230 may be integrally provided over the first to fourth organic light-emitting diodes OLED1, OLED2, OLED3, and OLED4.

The first pixel electrode 210-1, the second pixel electrode 210-2, the third pixel electrode 210-3, and the fourth pixel electrode 210-4 may be apart from each other, and may be located on the second upper insulating layer 118. The pixel electrode 210 includes a light-transmissive conductive layer and a reflective layer, wherein the light-transmissive conductive layer includes a light-transmissive conductive oxide, such as indium tin oxide (ITO), indium oxide (In₂O₃), or indium zinc oxide (IZO), and wherein the reflective layer includes metal, such as aluminum (Al) or silver (Ag). As an example, the pixel electrode 210 may have a three-layered structure of ITO/Ag/ITO.

As shown in FIG. 4, the pixel electrode 210 may be electrically connected to the thin-film transistor TFT by being in contact with one of the source electrode SE and the drain electrode DE. Alternatively, the pixel electrode 210 may be electrically connected to one of the source electrode SE and the drain electrode DE by being connected to the contact metal CM through a contact hole defined in the second upper insulating layer 118.

The bank layer 119 may be located on the second upper insulating layer 118 and the pixel electrode 210. The bank layer 119 defines the emission area by including an opening OP corresponding to the organic light-emitting diode OLED, that is, the opening OP exposing at least the central portion of the pixel electrode 210. For example, the bank layer 119 may include the first opening OP1, the second opening OP2, the third opening OP3, and the fourth opening OP4 described above with reference to FIG. 3. The first opening OP1 exposes the central portion of the first pixel electrode 210-1 of the first pixel P1, the second opening OP2 exposes the central portion of the second pixel electrode 210-2 of the second pixel P2, the third opening OP3 exposes the central portion of the third pixel electrode 210-3 of the third pixel P3, and the fourth opening OP4 exposes the central portion of the fourth pixel electrode 210-4 of the fourth pixel P4. Because the opening OP of the bank 119 defines the emission area of the organic light-emitting diode OLED, the size and/or width of the pixel may depend on the size and/or width of the opening OP of the bank layer 119.

The bank layer 119 may increase a distance between the pixel electrode 210 and the opposite electrode 230 (e.g., a distance between respective portions of the pixel electrode 210 and the opposite electrode 230), and thus, may reduce or prevent the likelihood of arcs and the like occurring at the edges of the pixel electrode 210. The bank layer 119 may include, for example, an organic material, such as polyimide or hexamethyldisiloxane (HMDSO).

The intermediate layer 220 may be located on the pixel electrode 210 and the bank layer 119. The intermediate layer 220 may include an emission layer 222 overlapping the pixel electrode 210. The emission layer 222 may include a first emission layer 222-1, a second emission layer 222-2, a third emission layer 222-3, and a fourth emission layer 222-4. The first emission layer 222-1, the second emission layer 222-2, and the third emission layer 222-3 may be configured to emit light of different or respective colors. As an example, the first emission layer 222-1 may be configured to emit red light, the second emission layer 222-2 may be configured to emit green light, and the third emission layer 222-3 may be configured to emit blue light. In one or more embodiments, the fourth emission layer 222-4 may be configured to emit white light. However, the present disclosure is not limited thereto. In one or more other embodiments, the fourth emission layer 222-4 may be configured to emit at least one of red, green, and/or blue light. The emission layer 222 may include an organic material. The emission layer 222 may include a polymer organic material or a low-molecular weight organic material configured to emit light having a corresponding color.

The intermediate layer 220 may further include at least one functional layer. As an example, the intermediate layer 220 may include a first functional layer 221 and a second functional layer 223 respectively located under and on the emission layer 222.

The first functional layer 221 may include a single layer or a multi-layer. As an example, in the case where the first functional layer 221 includes a polymer material, the first functional layer 221 may include a hole transport layer (HTL), which has a single-layered structure, and may include polyethylene dihydroxythiophene (PEDOT: poly-(3,4)-ethylene-dihydroxy thiophene) or polyaniline (PANI: polyaniline). In the case where the first functional layer 221 includes a low-molecular weight material, the first functional layer 221 may include a hole injection layer (HIL) and an HTL.

The second functional layer 223 may include a single layer or a multi-layer. In the case where the first functional layer 221 and the emission layer 222 include a polymer material, it may suitable that the second functional layer 223 is formed. The second functional layer 223 may include an electron transport layer (ETL) and/or an electron injection layer (EIL).

Each of the first functional layer 221 and the second functional layer 223 may be integrally formed to cover the display area DA entirely.

The opposite electrode 230 may include a conductive material having a relatively low work function. As an example, the opposite electrode 230 may include a (semi) transparent layer including silver (Ag), magnesium (Mg), aluminum (AI), nickel (Ni), chromium (Cr), lithium (Li), calcium (Ca) or an alloy thereof. Alternatively, the opposite electrode 230 may further include a layer on the (semi) transparent layer, the layer including ITO, IZO, ZnO, or In₂O₃. In one or more embodiments, the opposite electrode 230 may include silver (Ag) and magnesium (Mg).

A stack structure of the pixel electrode 210, the intermediate layer 220, and the opposite electrode 230, which are sequentially stacked, may form a light-emitting diode, for example, an organic light-emitting diode OLED. The organic light-emitting diode OLED may be configured to emit red, green, blue, or white light. The emission area of each organic light-emitting diode OLED corresponds to a pixel.

However, as described above, the fourth pixel P4 may include not only the organic light-emitting diode OLED, but also may include the light-receiving element. Referring to FIG. 4B, the other characteristics, except for the characteristic of a first light-receiving element PD, are the same as those described with reference to FIG. 4A. Same respective reference numerals among common elements of FIG. 4B are used with those previously described with reference to FIG. 4A, and differences are mainly described below.

Referring to FIG. 4B, the display apparatus 1 may include the substrate 100, the pixel circuit PC located on the substrate 100, and the organic light-emitting diode OLED and the light-receiving element PD located over the pixel circuit PC and electrically connected to the pixel circuit PC. Like the organic light-emitting diode OLED, the light-receiving element PD may be electrically connected to the pixel circuit PC, and thus, light detection may be controlled.

The first to third organic light-emitting diodes OLED1, OLED2, and OLED3, and the light-receiving element PD may be located apart from each other on the second upper insulating layer 118. The first to third organic light-emitting diodes OLED1, OLED2, and OLED3 may be configured to respectively emit light of different colors, and the light-receiving element PD may be configured to detect light emitted from the organic light-emitting diode OLED and reflected by an object.

Like the first to third organic light-emitting diodes OLED1, OLED2, and OLED3, the light-receiving element PD may include a fourth pixel electrode 210-4′, an intermediate layer 220-4′, and the opposite electrode 230. The first pixel electrode 210-1, the second pixel electrode 210-2, the third pixel electrode 210-3, and the fourth pixel electrode 210-4′ respectively of the first organic light-emitting diode OLED1, the second organic light-emitting diode OLED2, the third organic light-emitting diode OLED3, and the light-receiving element PD may be patterned for each pixel, and the opposite electrode 230 may be integrally provided over the organic light-emitting diodes OLED and the light-receiving element PD.

The intermediate layer 220-4′ of the light-receiving element PD may include an active layer 222-4 overlapping the fourth pixel electrode 210-4′. The active layer 222-4 configured to detect light may be located inside the fourth opening OP4 of the bank layer 119. That is, each of the first emission layer 222-1, the second emission layer 222-2, the third emission layer 222-3, and the active layer 222-4′ may be patterned for each pixel, and may be individually provided. The active layer 222-4′ may be configured to detect light in a visible light band emitted by the first to third organic light emitting diodes OLED1, OLED2, and OLED3 and reflected by an object. However, the present disclosure is not limited thereto, and a band of light that may be detected by the active layer 224-4′ may vary depending on the material that the active layer 222-4′ includes.

The active layer 222-4′ may include a p-type organic semiconductor and an n-type organic semiconductor. In this case, the p-type organic semiconductor may act as an electron donor, and the n-type organic semiconductor may act as an electron acceptor. Alternatively, the active layer 222-4′ may be a mixed layer in which the p-type organic semiconductor and the n-type organic semiconductor are mixed with each other. In this case, the active layer 222-4′ may be formed by co-depositing the p-type organic semiconductor and the n-type organic semiconductor. In the case where the active layer 222-4′ is a mixed layer, excitons may be generated within a diffusion length from a donor-acceptor interface.

In one or more embodiments, the p-type organic semiconductor may be a compound acting as an electron donor configured to supply electrons. For example, the p-type organic semiconductor may include boron subphthalocyanine chloride (SubPc), copper(II) phthalocyanine (CuPc), tetraphenyldibenzoperiplanthene (DBP), or any combination thereof, but the present disclosure is not limited thereto.

In one or more embodiments, the n-type organic semiconductor may be a compound acting as an electron acceptor configured to accommodate electrons. As an example, the n-type organic semiconductor may include C60 fullerene, C70 fullerene, or any combination thereof, but the present disclosure is not limited thereto.

A stack structure of the fourth pixel electrode 210-4, the intermediate layer 220-4 including the active layer 222-4, and the opposite electrode 230 that are sequentially stacked may form the light-receiving element. Accordingly, the display apparatus according to one or more other embodiments may be configured to improve a light-detecting function by efficiently incorporating the light-receiving element, and to secure suitable visibility by reducing a loss in an aperture ratio.

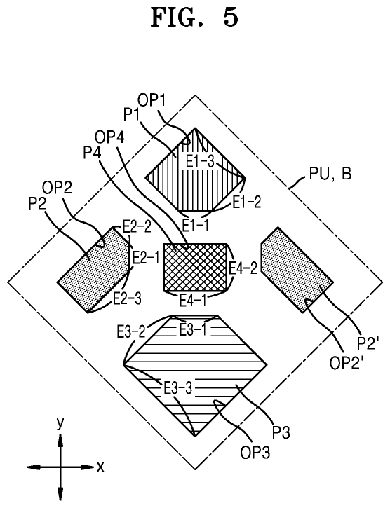

FIG. 5 is a plan view of some of pixels of FIG. 3. For example, FIG. 5 is an enlarged plan view of a region B of FIG. 3.

Referring to FIG. 5, the unit pixel PU may include one first pixel P1, two second pixels P2, one third pixel P3, and one fourth pixel P4. For example, the unit pixel PU may include the fourth opening OP4 arranged at the center of the unit pixel PU, the first opening OP1 arranged one row above the fourth opening OP4 in the first direction (e.g., the y direction), the third opening OP3 arranged one row below the fourth opening OP4 in the first direction (e.g., the y direction), and the second openings OP2 and OP2 arranged adjacent to the fourth opening OP4 with respect to the second direction (e.g., the x direction).

First, the fourth opening OP4 may have a quadrangular shape. For example, the fourth opening OP4 may include a first edge E4-1 of the fourth opening OP4 extending in the second direction (e.g., the x direction), and a second edge E4-2 of the fourth opening OP4 extending in the first direction (e.g., the y direction). In this case, the first edge E4-1 of the fourth opening OP4 may be greater than the second edge E4-2 of the fourth opening OP4, and accordingly, the fourth opening OP4 may be provided in a rectangular shape.

Next, the shape of each of the first to third openings OP1, OP2, and OP3 may have five or more interior angles. In one or more embodiments, as shown in FIG. 5, the first opening OP1, the second opening OP2, and the third opening OP3 may have a pentagonal shape. For example, the first opening OP1 and the third opening OP3 may have a pentagonal shape in which a corner portion is truncated from a square shape. In addition, the second opening OP2 may have a pentagonal shape in which a corner portion is truncated from a rectangular shape. In this case, a truncated corner of the corner portions of each of the first opening OP1, the second opening OP2, and the third opening OP3 may be a corner portion facing the fourth opening OP4.

Accordingly, the first opening OP1 may include a first edge E1-1 facing the fourth opening OP4. In addition, the first opening OP1 may include a second edge E1-2 arranged adjacent to the first edge E1-1 of the first opening OP1, and may include a third edge E1-3 that does not meet the first edge E1-1 of the first opening OP1. In this case, the first edge E1-1 of the first opening OP1 is a straight line parallel to the first edge E4-1 of the fourth opening OP4, and may be a straight line extending in the second direction (e.g., the x direction). The second edge E1-2 of the first opening OP1 and the third edge E1-3 of the first opening OP1 may be straight lines extending in an oblique direction with respect to the first direction (e.g., the y direction) and the second direction (e.g., the x direction). The second edge E1-2 of the first opening OP1 and the third edge E1-3 of the first opening OP1 may face respective second openings OP2.

The second opening OP2 may include a first edge E2-1 facing the fourth opening OP4. In addition, the second opening OP2 may include a second edge E2-2 and a third edge E2-3 arranged adjacent to the first edge E2-1 of the second opening OP2. In this case, the first edge E2-1 of the second opening OP2 is a straight line parallel to the second edge E4-2 of the fourth opening OP4, and may be a straight line extending in the first direction (e.g., the y direction). The second edge E2-2 of the second opening OP2 and the third edge E2-3 of the second opening OP2 may be straight lines extending in an oblique direction with respect to the first direction (e.g., the y direction) and the second direction (e.g., the x direction). The second edge E2-2 of the second opening OP2 and the third edge E2-3 of the second opening OP2 may respectively face the first opening OP1 and the third opening OP3.

The third opening OP3 may include a first edge E3-1 facing the fourth opening OP4. In addition, the third opening OP3 may include a second edge E3-2 arranged adjacent to the first edge E3-1 of the third opening OP3, and may include a third edge E3-3 that does not meet the first edge E3-1 of the third opening OP3. In this case, the first edge E3-1 of the third opening OP3 is a straight line parallel to the first edge E4-1 of the fourth opening OP4, and may be a straight line extending in the second direction (e.g., the x direction). The second edge E3-2 of the third opening OP3 and the third edge E3-3 of the third opening OP3 may be straight lines extending in an oblique direction with respect to the first direction (e.g., the y direction) and the second direction (e.g., the x direction). The second edge E3-2 of the third opening OP3 and the third edge E3-3 of the third opening OP3 may face respective ones of the second openings OP2.

In this case, to efficiently arrange the fourth opening OP4, the length of the first edge E1-1 of the first opening OP1 and the length of the first edge E3-1 of the third opening OP3 may be equal to or greater than the length of the first edge E2-1 of the second opening OP2. Accordingly, as described above, the fourth opening OP4 may have a rectangular shape in which the length of the first edge E4-1 of the fourth opening OP4 is greater than the length of the second edge E4-2 of the fourth opening OP4. This is to ensure suitable visibility by taking into account the area ratio of the first to third openings OP1, OP2, and OP3. However, the present disclosure is not limited thereto, and the length of the first edge E1-1 of the first opening OP1 and the length of the first edge E3-1 of the third opening OP3 are designed to be less than the length of the first edge E2-1 of the second opening OP2, and the fourth opening OP4 may be arranged in various shapes and sizes.

The length of the first edge E3-1 of the third opening OP3 may be equal to or greater than the length of the first edge E1-1 of the first opening OP1. In one or more embodiments, the length of the first edge E3-1 of the third opening OP3 may be designed to be equal to the length of the first edge E1-1 of the first opening OP1, or a little greater than the length of the length of the first edge E1-1 of the first opening OP1. That is, as in FIG. 5, when designing the first opening OP1 and the third opening OP3 in a pentagonal shape in which a corner portion is truncated from a quadrangle, the region of the corner portions truncated may be designed to be substantially equal. In this case, because the area of the third opening OP3 is greater than the area of the first opening OP1 (that is, the length of the third edge E3-3 of the third opening OP3 is greater than the length of the third edge E1-3 of the first opening OP1), a value of the second edge E3-2 of the third opening OP3 compared to the first edge E3-1 of the third opening OP3(E3-2/E3-1) may be greater than a value of the second edge E1-2 of the first opening OP1 compared to the first edge E1-1 of the first opening OP1(E1-2/E1-1).

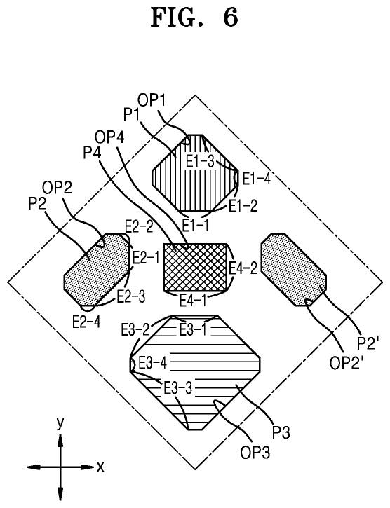

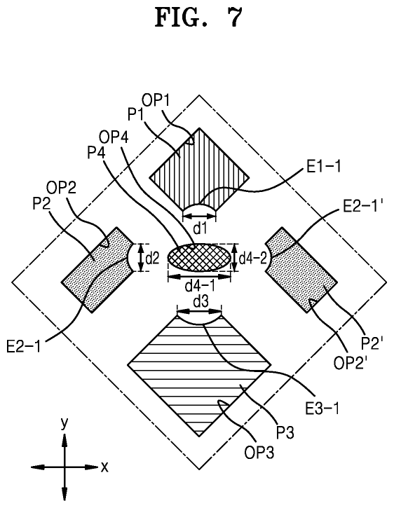

FIGS. 6 and 7 are plan views of some pixels of a display apparatus according to one or more other embodiments. Referring to FIGS. 6 and 7, the other characteristics except for the characteristic of the shape of the first to fourth openings OP1, OP2, OP3, and OP4 are the same as those described with reference to FIGS. 3 to 5. Same respective reference numerals among elements of FIGS. 6 and 7 are used with those previously described with reference to FIGS. 3 to 5, and differences are mainly described below.

First, referring to FIG. 6, the first opening OP1, the second opening OP2, and the third opening OP3 may have an octagonal shape. For example, the first opening OP1 and the third opening OP3 may have an octagonal shape in which all of four corner portions are truncated from a square shape. In addition, the second opening OP2 may have an octagonal shape in which all of four corner portions are truncated from a rectangular shape.

Accordingly, the first opening OP1 may further include a fourth edge E1-4 in addition to the first edge E1-1 of the first opening OP1, the second edge E1-2 of the first opening OP1, and the third edge E1-3 of the first opening OP1. That is, as in FIG. 6, in the case where the first opening OP1 has an octagonal shape in which a corner portion is truncated from a quadrangle, the fourth edge E1-4 of the first opening OP1 may be an edge facing the region of the truncated corner portion. For example, the fourth edge E1-4 of the first opening OP1 may be a straight line connecting the second edge E1-2 of the first opening OP1 and the third edge E1-3 of the first opening OP1 to each other. Accordingly, the fourth edge E1-4 of the first opening OP1 may be a straight line extending in the first direction (e.g., the y direction). However, the present disclosure is not limited thereto, and the fourth edge E1-4 of the first opening OP1 may be a curve in one or more other embodiments. That is, regions of the corner portions of the first opening OP1 except for the corner portion that is in contact with the first edge E1-1 of the first opening OP1 may have a round shape.

However, as in FIG. 6, in the case where the first opening OP1 has an octagonal shape, regions of the corner portions that do not face the fourth opening OP4 among the regions of the truncated corner portions may have areas that are smaller than the area of a region of the truncated corner portion facing the fourth opening OP4. That is, in one or more embodiments, the length of the fourth edge E1-4 of the first opening OP1 may be less than the length of the first edge E1-1 of the first opening OP1.

Likewise, the second opening OP2 may further include a fourth edge E2-4 in addition to the first edge E2-1 of the second opening OP2, the second edge E2-2 of the second opening OP2, and the third edge E2-3 of the second opening OP2. That is, as in FIG. 6, in the case where the second opening OP2 has an octagonal shape in which a corner portion is truncated from a quadrangle, the fourth edge E2-4 of the second opening OP2 may be an edge facing the region of the truncated corner portion. For example, the fourth edge E2-4 of the second opening OP2 may be a straight line connected to the third edge E2-3 of the second opening OP2. Accordingly, the fourth edge E2-4 of the second opening OP2 may be a straight line extending in the second direction (e.g., the x direction). However, the present disclosure is not limited thereto, and the fourth edge E2-4 of the second opening OP2 may be a curve in one or more other embodiments. That is, regions of the corner portions of the second opening OP2 except for the corner portion that is in contact with the first edge E2-1 of the second opening OP2 may have a round shape.

However, as in FIG. 6, in the case where the second opening OP2 has an octagonal shape, regions of the corner portions that do not face the fourth opening OP4 among the regions of the truncated corner portions may have areas that are less than the area of a region of the truncated corner portion facing the fourth opening OP4. That is, in one or more embodiments, the length of the fourth edge E2-4 of the second opening OP2 may be less than the length of the first edge E2-1 of the second opening OP2.

Similarly, the third opening OP3 may further include a fourth edge E3-4 in addition to the first edge E3-1 of the third opening OP3, the second edge E3-2 of the third opening OP3, and the third edge E3-3 of the third opening OP3. That is, as in FIG. 6, in the case where the third opening OP3 has an octagonal shape in which a corner portion is truncated from a quadrangle, the fourth edge E3-4 of the third opening OP3 may be an edge facing the region of the truncated corner portion. For example, the fourth edge E3-4 of the third opening OP3 may be a straight line connecting the second edge E3-2 of the third opening OP3 and the third edge E3-3 of the third opening OP3 to each other. Accordingly, the fourth edge E3-4 of the third opening OP3 may be a straight line extending in the second direction (e.g., the x direction). However, the present disclosure is not limited thereto, and the fourth edge E3-4 of the third opening OP3 may be a curve in one or more other embodiments. That is, regions of the corner portions of the third opening OP3 except for the corner portion that is in contact with the first edge E3-1 of the third opening OP3 may have a round shape.

However, as in FIG. 6, in the case where the third opening OP3 has an octagonal shape, regions of the corner portions that do not face the fourth opening OP4 among the regions of the truncated corner portions may have areas less than the area of a region of the truncated corner portion facing the fourth opening OP4. That is, in one or more embodiments, the length of the fourth edge E3-4 of the third opening OP3 may be less than the length of the first edge E3-1 of the third opening OP3.

Next, referring to FIG. 7, the fourth opening OP4 may have a closed curve shape. As an example, the fourth opening OP4 may have a circular shape, an elliptical shape, or a curved shape. In one or more embodiments, the fourth opening OP4 may have an elliptical shape as in FIG. 7. In this case, the fourth opening OP4 may have an elliptical shape having a major axis or length d4-1 in the second direction (e.g., x direction) and a minor axis or length d4-2 in the first direction (e.g., y direction). However, the present disclosure is not limited thereto, and the fourth opening OP4 may have an elliptical shape having a major axis in the first direction (e.g., the y direction).

In this case, the shape of each of the first to third openings OP1, OP2, and OP3 may have five or more interior angles. Like FIG. 5, the first opening OP1 and the third opening OP3 may have a shape in which a corner portion is truncated from a square shape, and the second opening OP2 may have a shape in which a corner portion is truncated from a rectangular shape. However, in FIG. 7, the first opening OP1, the second opening OP2, and the third opening OP3 may include an edge that is parallel to, or complimentary to, a boundary line of the fourth opening OP4. That is, in the case where the fourth opening OP4 has a circular shape or an elliptical shape, the first edge E1-1 of the first opening OP1, the first edge E2-1 of the second opening OP2, and the first edge E3-1 of the third opening OP3 may be curved.

In addition, to efficiently arrange the fourth opening OP4, a length d1 of the first edge E1-1 of the first opening OP1 and a length d3 of the first edge E3-1 of the third opening OP3 may be equal to or greater than a length d2 of the first edge E2-1 of the second opening OP2. Accordingly, the fourth opening OP4 may have an elliptical shape having a major axis in the second direction (e.g., the x direction). This is to ensure suitable visibility by accounting for the area ratio of the first to third openings OP1, OP2, and OP3. However, the present disclosure is not limited thereto, and the length d1 of the first edge E1-1 of the first opening OP1 and the length d3 of the first edge E3-1 of the third opening OP3 are designed to be less than the length d2 of the first edge E2-1 of the second opening OP2, and the fourth opening OP4 may be arranged in various shapes and sizes. In addition, in this case, the length d1 of the first edge E1-1 of the first opening OP1 may denote a straight length or a curved length of both ends of the first edge E1-1 of the first opening OP1. Likewise, the length d2 of the first edge E2-1 of the second opening OP2 may denote a straight length or a curved length of both ends of the first edge E2-1 of the second opening OP2, and the length d3 of the first edge E3-1 of the third opening OP3 may denote a straight length or a curved length of both ends of the first edge E3-1 of the third opening OP3.

In the display apparatus according to one or more other embodiments as in FIGS. 6 and 7, while the shapes of the first to fourth openings OP1, OP2, OP3, and OP4 are variously arranged, suitable visibility may be implemented. That is, embodiments may provide a display apparatus with a reduced loss of an aperture ratio, and improved display quality while elements that may be embedded in the fourth opening OP4 are efficiently arranged.

Embodiments may provide a display apparatus with a reduced loss of an aperture ratio while various sensors and/or elements may be embedded therein. However, this aspect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a substrate;
a first organic light-emitting diode configured to emit light of a first color, a second organic light-emitting diode configured to emit light of a second color, and a third organic light-emitting diode configured to emit light of a third color above the substrate; and
a bank layer defining a first opening, second openings, and a third opening, the first opening overlapping the first organic light-emitting diode, at least one of the second openings overlapping the second organic light-emitting diode, and the third opening overlapping the third organic light-emitting diode,
wherein the bank layer further defines a fourth opening arranged between the first opening and the third opening in plan view,
wherein the first opening, the second openings, and the third opening comprise respective edges substantially parallel to, or substantially complimentary to, respective boundary lines of the fourth opening, and
wherein the first opening, the second openings, and the third opening comprise five or more interior angles.

2. The display apparatus of claim 1, wherein the second openings are arranged along a first column in a first direction,
wherein the first opening and the third opening are alternately arranged along a second column parallel to the first column,
wherein the second openings are staggered from the first opening and the third opening in the first direction,
wherein the first column and the second column are alternately arranged in a second direction crossing the first direction, and
wherein the fourth opening is arranged between the first opening and the third opening along the second column.

3. The display apparatus of claim 2, wherein the second openings are arranged along a first row in the second direction,
wherein the first opening and the third opening are alternately arranged along a second row parallel to the first row,
wherein the second openings are arranged in a staggered manner relative to the first opening and the third opening in the second direction,
wherein the first row and the second row are alternately arranged in the first direction, and
wherein the fourth opening is arranged between respective adjacent ones of the second openings along the first row.

4. The display apparatus of claim 2, wherein a unit pixel is repeatedly arranged in the first direction and the second direction on the substrate, the unit pixel comprising:
the fourth opening at a center of the unit pixel;
the first opening and the third opening adjacent to the fourth opening in the first direction; and
the second openings adjacent to two sides of the fourth opening in the second direction.

5. The display apparatus of claim 2, wherein a number of fourth openings above the substrate is equal to a number of first openings above the substrate.

6. The display apparatus of claim 2, wherein, in a plan view, a virtual quadrangle has one of the second openings as a center, and
wherein first openings are respectively arranged on a first vertex and a third vertex of the virtual quadrangle opposite each other, and third openings are respectively arranged on a second vertex and a fourth vertex of the virtual quadrangle.

7. The display apparatus of claim 6, wherein the vertices of the virtual quadrangle are respectively at centroids of the first openings and the third openings in plan view.

8. The display apparatus of claim 2, wherein the second openings arranged adjacent to each other in the second direction with the fourth opening therebetween have symmetrical shapes with each other with respect to a virtual straight line passing through a center of the fourth opening in the first direction.

9. The display apparatus of claim 2, wherein a shape of the fourth opening is a quadrangle in plan view, and respective edges of the first opening, the second openings, and the third opening that face the fourth opening are straight.

10. The display apparatus of claim 9, wherein the first opening, the second openings, and the third opening respectively have a pentagonal shape in plan view.

11. The display apparatus of claim 9, wherein the fourth opening comprises a first edge extending in the second direction, and a second edge extending in the first direction, and
wherein the first opening comprises a first edge facing the fourth opening, the second openings comprise first edges facing the fourth opening, and the third opening comprises a first edge facing the fourth opening.

12. The display apparatus of claim 11, wherein a length of the first edge of the fourth opening is greater than a length of the second edge of the fourth opening, and
wherein the shape of the fourth opening is rectangular.

13. The display apparatus of claim 11, wherein the first edge of the first opening and the first edge of the third opening are equal to or greater than the first edges of the second openings in length.

14. The display apparatus of claim 11, wherein the first edge of the third opening is equal to or greater than the first edge of the first opening in length.

15. The display apparatus of claim 11, wherein the first opening further comprises a second edge adjacent to the first edge of the first opening, wherein the third opening further comprises a second edge adjacent to the first edge of the third opening, and
wherein a length of the second edge of the third opening is greater than a length of the second edge of the first opening.

16. The display apparatus of claim 9, wherein respective corner portions of the first opening, the second openings, and the third opening have a round shape in plan view.

17. The display apparatus of claim 9, wherein the first opening, the second openings, and the third opening respectively have an octagonal shape in plan view.

18. The display apparatus of claim 2, wherein a shape of the fourth opening is a circular shape or an elliptical shape in plan view, and
wherein respective edges of the first opening, the second openings, and the third opening that face the fourth opening are curved.

19. The display apparatus of claim 1, wherein the first color is red, the second color is green, and the third color is blue.

20. The display apparatus of claim 1, further comprising a fourth organic light-emitting diode overlapping the fourth opening, and configured to emit light of at least one of red, green, blue, or white.

21. The display apparatus of claim 1, further comprising a light-receiving element overlapping the fourth opening.
